(19) United States
(12) Patent Application Publication
(10) Pub. No.: US 2006/0211253 A1
(43) Pub. Date: Sep. 21, 2006

(54) Method and apparatus for monitoring plasma conditions in an etching plasma processing facility

(76) Inventors: Ing-shin Chen, Danbury, CT (US); Jeffrey W. Neuner, Bethel, CT (US)

Correspondence Address: INTELLECTUAL PROPERTY / TECHNOLOGY LAW, PO BOX 14329, RESEARCH TRIANGLE PARK, NC, 27709, US

(21) Appl. No.: 11/081,439

(22) Filed: Mar. 16, 2005

(51) Int. Cl. H01L 21/302; G01L 21/30; C23F 1/00

(52) U.S. Cl. 438/714; 216/59; 156/345.27

(57) ABSTRACT

The present invention relates to a method and system of using downstream sensor elements for determining the plasma conditions (e.g., plasma etching end point) in a semiconductor etching facility that utilizes halogen-containing plasma and/or oxygen-containing plasma. Such sensor elements are capable of exhibiting temperature change in the presence of energetic gas species, e.g., fluorine, chlorine, iodine, bromine, oxygen, and derivatives and radicals thereof that are generated by the plasma, and correspondingly generating an output signal indicative of such temperature change for determination of the plasma conditions in the etching plasma processing facility.

### BACKGROUND OF THE INVENTION

1. Field of the Invention

The present invention relates generally to a method and a system for determining plasma conditions in an etching plasma processing facility, by sensing one or more energetically active gas species, such as fluorine, chlorine, iodine, bromine, oxygen, and derivatives or radicals thereof that have been energetically activated for etching purposes, at a location downstream of such etching plasma processing facility.

2. Description of the Related Art

Etching plasma has been widely used in semiconductor industry for etching and chemical vapor deposition (CVD) cleaning purposes. The plasma is utilized as an energy medium to generate highly reactive species by breaking apart gas molecules from the feedstock, and such highly reactive species scavenge the materials either on the wafer or the chamber wall to form volatile reaction products that can be easily removed.

Currently in etching operations, etch endpoints are reached when a prescribed amount of time has elapsed. Over etch, in which the process gas continues to flow into the reactor chamber after the cleaning etch is finished, is common and leads to longer process cycles, reduced tool lifetimes, and unnecessary release of fluoro species to the atmosphere.

Various analytical techniques, such as Langmuir probes, FTIR, optical emission spectroscopy, and ionized mass spectroscopy, have been used to monitor the etching process.

However, these techniques tend to be expensive, and often require a dedicated operator due to their complexity. Further, they are generally considered impractical for in-line adoption for continuous monitoring due to their operational constraints.

It would therefore be a significant advance in the art to provide a reliable, low-cost sensing method and apparatus that will serve to improve the throughput and chemical efficiency of the equipment used for monitoring the etching and cleaning process, by reducing and optimizing clean and etch times, and hence reducing chemical usage, lengthening equipment operating life, and decreasing equipment down time.

### SUMMARY OF THE INVENTION

The present invention relates generally to method and apparatus for determining the plasma conditions in an etching plasma processing facility, by monitoring presence and concentration of energetically active gas species in an effluent gas stream generated by the etching plasma processing facility at a location downstream of such etching plasma processing facility.

In one aspect, the present invention relates to a method for determining plasma conditions in an etching plasma processing facility, comprising the steps of:

providing at least one sensor element capable of exhibiting temperature change in presence of energetic gas species and correspondingly generating an output signal indicative of said temperature change;

contacting the sensor element with an effluent gas stream generated by such etching plasma processing facility at a location downstream of such etching plasma processing facility; and

determining the plasma conditions in such etching plasma processing facility, based on the output signal generated by the sensor element that is indicative of temperature change caused by the presence of energetic gas species in the effluent gas stream.

Such sensor element in one embodiment of the present invention may comprise at least two components that contain different metals or metal alloys and have a thermojunction therebetween. The thermojunction in such sensor element, upon contact with energetically active gas species in the effluent gas stream, generates a voltage differential correlative to temperature change caused by the presence of such energetically active gas species in the effluent gas stream, which can be used for determining the plasma conditions (e.g., plasma etching end point) in the etching plasma processing facility.

In another embodiment, the sensor element comprises a thermistor, a resistance temperature detector (RTD), or any other probe that is capable of exhibiting temperature change in the presence of energetic gas species and correspondingly generating an output signal indicative of said temperature change.

The energetic gas species that cause temperature change in the sensor element include, but are not limited to, fluorine, chlorine, iodine, bromine, oxygen, and derivatives and radicals thereof as generated by plasma conditions. Such energetic gas species are energy-carrying neutrals that have a relatively longer lifetime than the charged particles generated by the plasma conditions, and are capable of reaching a probe surface downstream of the etching plasma processing facility to impart energy on the probe surface via inelastic collisions and/or exothermic recombination.

In a further aspect, the present invention relates to a system for determining plasma conditions in an etching plasma processing facility, which comprises:

a gas sampling device for obtaining a gas sample from an effluent gas stream generated by the etching plasma processing facility at a location downstream of such etching plasma processing facility;

at least one sensor element operatively coupled with the gas sampling device for exposure to the gas sample, wherein such sensor element is capable of exhibiting temperature change in presence of energetic gas species and correspondingly generating an output signal indicative of the temperature change;

a monitoring assembly operatively coupled with the sensor element for monitoring the output signal generated by the sensor element that is indicative of temperature change caused by the presence of energetic gas species in such gas stream and determining the plasma conditions in the etching plasma processing facility based on the output signal.

As used herein, the term “fluoro species” or “fluorine” is intended to be broadly construed to encompass all fluorine-containing materials, including without limitation, gaseous fluorine compounds, fluorine per se in atomic and diatomic (F₂) forms, fluorine ions, and fluorine-containing ionic species, which are energetically activated under plasma conditions. The fluoro species may include activated fluorine-containing species, such as NF₃, SiF₄, C₂F₆, HF, F₂, COF₂, ClF₃, IF₃, etc. in ionized or plasma forms.

As used herein, the term “chlorine species” or “fluorine” is intended to be broadly construed to encompass all chlorine-containing materials, including without limitation, gaseous chlorine compounds, chlorine per se in atomic and diatomic (Cl₂) forms, chlorine ions, and chlorine-containing ionic species, which are energetically activated under plasma conditions. The chlorine species may include activated chlorine-containing species, such as NCl₃, SiCl₄, C₂Cl₆, HCl, Cl₂, COCl₂, ClF₃, ICl₃, etc. in ionized or plasma forms.

As used herein, the term “bromine species” or “bromine” is intended to be broadly construed to encompass all bromine-containing materials, including without limitation, gaseous bromine compounds, bromine per se in atomic and diatomic (Br₂) forms, bromine ions, and bromine-containing ionic species, which are energetically activated under plasma conditions.

As used herein, the term “iodine species” or “iodine” is intended to be broadly construed to encompass all iodine-containing materials, including without limitation, gaseous iodine compounds, iodine per se in atomic and diatomic (I₂) forms, iodine ions, and iodine-containing ionic species, which are energetically activated under plasma conditions.

As used herein, the term “oxygen species” or “oxygen” is intended to be broadly construed to encompass all oxygen-containing materials, including without limitation, gaseous oxygen compounds, oxygen per se in atomic, diatomic (O₂), or triatomic (O₃) forms, oxygen ions, and oxygen-containing ionic species, which are energetically activated under plasma conditions. The oxygen species may include activated oxygen-containing species, such as H₂O, NO, NO₂, N₂O, etc. in ionized or plasma forms.

As used herein, the term “metal or metal alloys” is intended to be broadly construed to encompass all metals or alloys of metals in their elemental form as well as conductive metal compounds such as metal suicides and/or metal nitrides.

Other aspects, features and embodiments of the invention will be more fully apparent from the ensuing disclosure and appended claims.

### BRIEF DESCRIPTION OF THE DRAWINGS

FIG. 1 shows a wishbone-shaped sensor element containing a copper filament and a constantan filament joined together at first ends thereof, according to one embodiment of the present invention.

FIG. 2 shows a Teflon®-coated sensor element, according to one embodiment of the present invention.

FIG. 3 shows the output signals of a sensor element in exposure to NF₃ plasma containing activated fluoro species, in side-by-side comparison with the fluorine partial pressure as measured by a residue gas analyzer (RGA).

FIG. 4 shows the response signals of a sensor element as a function of NF₃ composition under different pressures and gas flow rates, according to one embodiment of the present invention.

### DETAILED DESCRIPTION OF THE INVENTION, AND PREFERRED EMBODIMENTS THEREOF

Thermal probes have been employed for studying the integral energy flux from plasma towards a location inside the plasma processing facility, such as the wafer substrate or the plasma reaction chamber wall. The integral energy flux experienced by such in situ thermal probes is the sum of energy fluxes carried by charged particles, neutrals, and photons present in the plasma as they impinge on the probe surface.

In contrast, the present invention employs downstream thermal probes, instead of in situ energy probes, for monitoring energy flux from an effluent gas stream generated by the plasma processing facility at a downstream location away from the plasma conditions.

At such downstream location, only energy fluxes carried by energetic neutrals, such as fluorine, chlorine, iodine, bromine, oxygen, and derivatives and radicals thereof, which are characterized by longer lifetime than charged particles and photons, may reach the surface of such downstream thermal probes. Because the intensity of the energy fluxes carried by such energetic neutrals correlates with the plasma conditions quantitatively, it can be advantageous used for downstream determination of the plasma conditions in the etching plasma processing facility.

Therefore, in one embodiment of the present invention, a sensor element, which is capable of exhibiting temperature change in the presence of the above-described energetic neutral species and correspondingly generating an output signal indicative of said temperature change, is exposed to an effluent gas stream generated by the etching plasma processing facility at a location downstream of the etching plasma processing facility, for monitoring the energy fluxes carried by such energetic neutrals in the effluent gas stream. For example, such sensor element may be operatively coupled with a gas sampling device, either coupled to a downstream fluid flow path or constituting a part of such fluid flow path, for obtaining a gas sample from the effluent gas stream at such downstream location and exposing the sensor element to the gas sample.

The energetic neutrals, if present in the effluent gas stream, therefore reach the surface of such downstream sensor element to impart energy on the sensor surface via inelastic collisions and/or release reaction energy by exothermic recombination thereof on the sensor surface, causing detectable temperature change on the surface of such sensor element. Such temperature change is correlative to the presence and concentration of the energetic neutrals in the effluent gas stream, and is therefore useful for inferring the plasma conditions in the etching plasma processing facility.

Preferably, such sensor element comprises two different metal components joined together with a heterojunction therebetween, which exhibits detectable change in the voltage differential between the two components of the sensor element in the presence of energetic gas species. Such change in the voltage differential quantitatively correlates with the concentration of the energetic gas species in the effluent gas stream, and can be monitored by a monitoring device for inferring the plasma conditions in said etching plasma processing facility.

The specific structure, composition, and surface condition of such sensor element are not critical for the practice of the present invention.

Preferably, when the effluent gas stream is susceptible to presence of energetic fluoro species or other halogen species, such sensor element comprises materials that are resistant to corrosion or attack by the fluoro species or other halogen species, or is otherwise protected from such corrosion or attack, e.g., by a fluoro- or halogen-resistant coating. For instance, the two components of such sensor element may be formed by metal filaments containing metals or metal alloys such as nickel, aluminum, and copper, and alloys thereof, and such metal filaments may have an average diameter of from about 0.1 micron to about 1000 microns.

A particular preferred type of sensor element for practicing the present invention is a sensor element that comprises a first component made of copper and a second component made of a copper-nickel alloy such as constantan. Both copper and nickel are fluoro-resistant, and such sensor element can therefore be used for detecting energetic fluoro species.

Further, the sensor element may comprise a fluoro-resistant coating that protects the two metal components of the sensor element from corrosion and attack by the fluoro species. For example, such sensor element may have a coating formed of polytetrafluoroethylene, alumina, Group II metal fluorides (such as CaF₂ and MgF₂), and perfluorinated polymers (such as polyimide materials commercialized by DuPont under the trademark Vespel®). Still further, such fluoro-resistant coating functions to insulate the metal components of the sensor element and thereby avoid inadvertent contact of the metal components with external conductors or conducting materials, which may interfere with the measurement of the voltage differential.

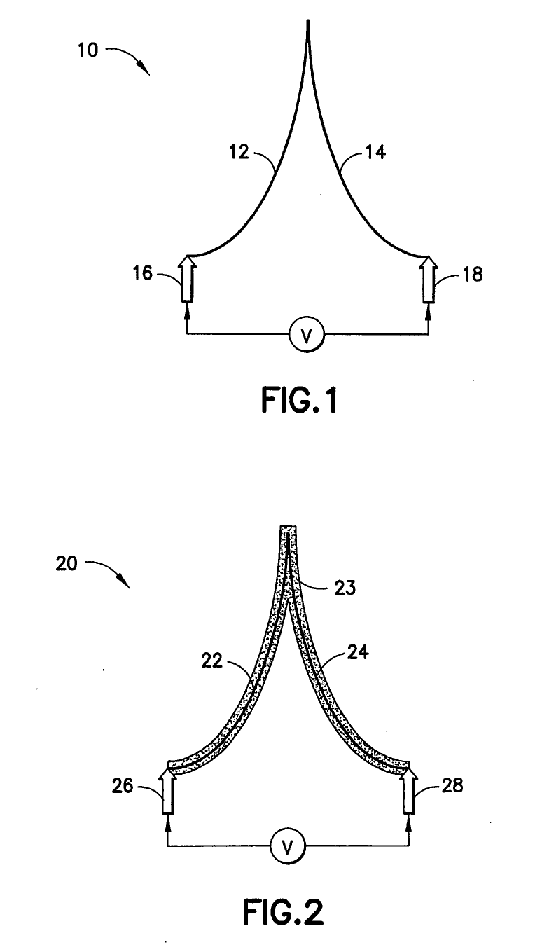

FIG. 1 shows an exemplary wishbone-shaped sensor element 10, which contains a first component 12 formed of a copper filament and a second component 14 formed of a constantan filament as joined at one ends thereof to form a heterothermojunction. The other ends of the first and second components 12 and 14 are fixed to or otherwise mounted onto two electrical contacts or terminals 16 and 18, and a monitoring and signaling device (not shown) as described hereinabove can be used to monitor the voltage differential between these two terminals 16 and 18 for determining presence and concentration of the fluoro species.

FIG. 2 shows another exemplary sensor element 20, which contains a first component 22 and a second component 24 formed of different metals or metal alloys. A fluoro-resistant coating 23 containing polytetrafluoroethylene insulates both components as well as protects such from attack by the corrosive fluoro species. The first and second components 22 and 24 are joined at one ends thereof to form a heterojunction and fixed to or otherwise mounted onto two electrical contacts or terminals 26 and 28, to which a monitoring and signaling device (not shown) can be electrically coupled for monitoring the voltage differential between these two terminals 26 and 28.

Measurement of the voltage differential between the two components of the sensor element can be readily achieved by a voltmeter with a simple signal amplification element, or any other suitable instruments or apparatus. Preferably, cold thermojunction compensation (CJC) techniques are used to compensate for the impact of any additional heterojunction formed between the sensor element and the measuring instrument and to ensure accurate measurement of the voltage differential.

Signal measurement for the above-described sensor element is simple and straightforward, and a person ordinarily skilled in the art can readily determine the components and configuration of the monitoring and signaling device, without undue experimentation. More importantly, the signal measurement for such sensor element of the present invention is passive, i.e., no external energy is required for the operation of such sensors.

Alternatively, the sensor element of the present invention may comprise any other thermal probes, including but not limited to thermistors and resistance temperature detectors (RTDs). The RTD may operate in measurement mode where its resistance is read without modification. Alternatively, the RTD may operate in constant resistance or constant current control mode, where the resistance of such RTD or the current that passes through such RTD is manipulated to maintain at a prescribed, constant value, for example, by varying the electrical power delivered to it. In the latter case, the manipulated power provides an indirect temperature measurement.

Although the above-description is primarily directed to detection of energetic fluoro species, the present invention can be readily applied to other energetic gas species, including but not limited to chlorine, iodine, bromine, oxygen, and derivatives and radicals thereof.

The gas-sensing system of the present invention may include a single gas sensor as described hereinabove, or a plurality of such gas sensors, wherein the multiple gas sensor elements provide redundancy or back-up sensing capability, or in which different ones of the multiple sensor elements are arranged for sensing of different energetic gas species in the stream or gas volume being monitored, or in which different ones of the sensor elements in the array are operated in different modes, or in interrelated modes, such as for production of respective signals that are algorithmically manipulated, e.g., subtractively, to generate a net indicating signal, or alternatively, additively to produce a composite indicating signal, or in any other suitable manner in which the multiplicity of sensor elements is efficaciously employed to monitor the energetic gas species in the stream or fluid volume of interest, for generation of correlative signal(s) for monitoring or control purposes.

In connection with the use of arrays of gas-sensing elements, advanced data processing techniques can be used to enhance the output of the sensor system. Examples of such techniques include, but are not limited to, the use of compensating signals, the use of time-varying signals, heater currents, lock-in amplifying techniques, signal averaging, signal time derivatives, and impedance spectroscopy techniques. In addition, advanced techniques that fall into the category of chemometrics may also be applied. These techniques include least squares fitting, inverse least squares, principal component regression, and partial least square data analysis methods.

The gas-sensing element(s) of the invention may therefore be coupled in a suitable manner, within the skill of the art, to transducers, computational modules, or other signal processing units, to provide an output indicative of the present or change in amount of one or more energetic gas species in the fluid environment being monitored.

### EXAMPLE

A test was conducted to determine the response of a sensor element as illustrated by FIG. 1 when exposed to NF₃ plasma that contains energetic fluoro species.

The plasma source was an ASTRON AX 7650 Atomic Fluorine Generator by ASTeX operating at 400 kHz and 6 kW. Mass flow controllers were used to control process gas (Ar and NF₃) flows. A specimen port immediately at the plasma source outlet allowed insertion of test specimens such as silicon wafers. The transfer tube was made of 6061 T6 Aluminum, and there were multiple ports along the transport tube for thermal probe installation. A capacitance manometer was used to provide pressure readings, and a throttle valve was used to control the transfer tube pressure.

With respect to the sensor element, a copper filament and a constantan filament of about 0.005 inch in diameter (as purchased from Omega Engineering, Inc. at Stamford, Conn.) were spot-welded together at first ends thereof to form a sensor element with a heterojunction at the welding point. Such sensor element was then attached to a sensor element vacuum feedthrough with copper and constantan connectors (as purchased from CeramTec North America Corp. at Laurens, S.C.), which were in turn coupled to a signal converter for automatic conversion of the voltage differential reading into a temperature reading.

Five deposition/cleaning cycles were simulated. Specifically, the deposition cycles were simulated by providing nitrogen purge at 70 mTorr, and the cleaning cycles were simulated by providing active plasma with argon at 5 Torr and about 1 standard liter per minute (slm). At the mid-point of each cleaning cycle, 500 sccm of NF₃ was gradually added over a 15-second interval to simulate a fluorine rising endpoint for the NF₃ plasma cleaning.

An RGA300 Residue Gas Analyzer by Stanford Research Systems was used to track the temporal evolution of chemical species, specifically the actual fluorine concentration in the test manifold, which scanned a full 100 atomic mass unit spectrum every 10 seconds. Mass 38 was plotted as the indicator for fluorine (F₂) concentration in the test manifold.

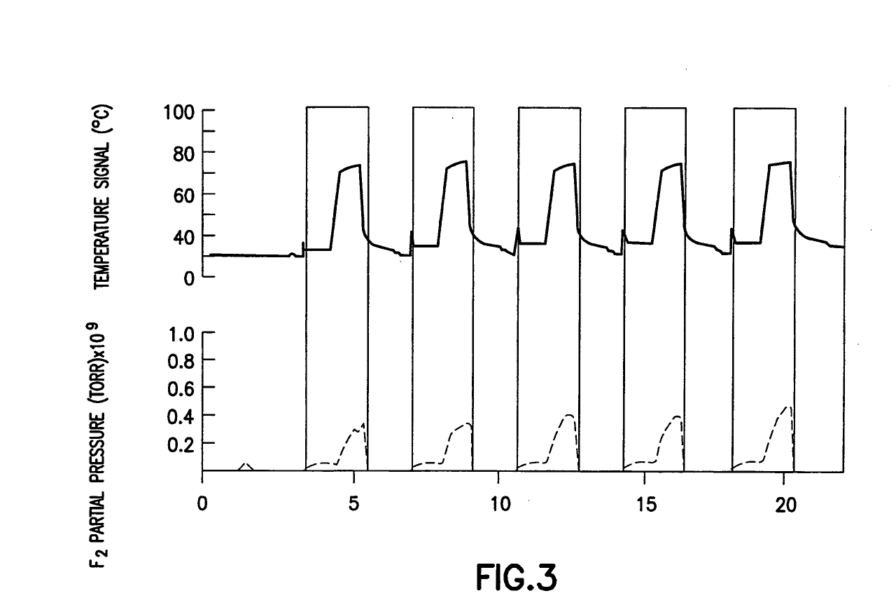

FIG. 3 shows the temperature readings of the sensor element through such five simulated deposition/cleaning cycles, in comparison with the fluorine concentration readings of the RGA. Clearly, the temperature readings of the sensor element-based sensor of the present invention correlate well with the fluorine concentration readings of the RGA.

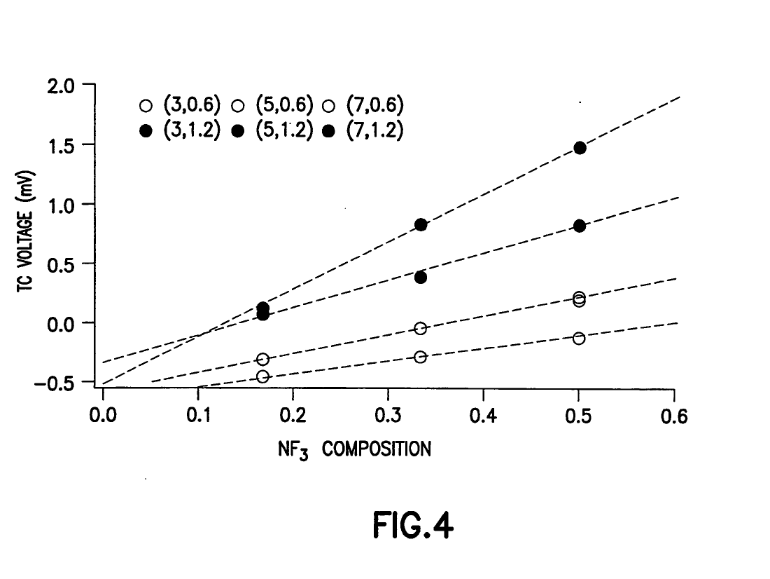

Further, a 2×3 matrix design of experiment was executed to study the sensor response characteristics. Specifically, the transfer tube pressure was varied between 3, 5, and 7 torr, while the total gas flow was varied between 0.6 and 1.2 SLM. At each combination of transfer tube pressure and total gas flow, NF₃ composition was varied between ⅙, 2/6, and 3/6, by volume of the total gas feed. The signal dependence on NF₃ composition and corresponding test conditions are shown on FIG. 4 for the entire design of experiment matrix. There is a linear correlation between the sensor response and NF₃ composition, from which quantitative parameters can be derived to reproduce the response characteristics.

Although the invention has been variously described herein with reference to illustrative embodiments and features, it will be appreciated that the embodiments and features described hereinabove are not intended to limit the invention, and that other variations, modifications and other embodiments will readily suggest themselves to those of ordinary skill in the art, based on the disclosure herein. The invention therefore is to be broadly construed, consistent with the claims hereafter set forth.

What is claimed is:

1. A method for determining plasma conditions in an etching plasma processing facility, comprising the steps of:
providing at least one sensor element capable of exhibiting temperature change in presence of energetic gas species and correspondingly generating an output signal indicative of said temperature change;
contacting said sensor element with an effluent gas stream generated by said etching plasma processing facility at a location downstream of said etching plasma processing facility; and
determining the plasma conditions in said etching plasma processing facility, based on the output signal generated by said sensor element that is indicative of temperature change caused by the presence of energetic gas species in said effluent gas stream.

2. The method of claim 1, wherein said sensor element comprises at least two components that contain different metals or metal alloys and have a thermojunction therebetween.

3. The method of claim 2, wherein the at least two components of said sensor element contain metals or metal alloys selected from the group consisting of nickel, aluminum, copper, and alloys thereof.

4. The method of claim 2, wherein the effluent gas stream is susceptible to the presence of energetic fluoro species, and wherein said at least two components of the sensor element contain fluoro-resistant metals or metal alloys.

5. The method of claim 2, wherein said sensor element comprises a first component containing copper, and a second component containing constantan.

6. The method of claim 2, wherein the effluent gas stream is susceptible to the presence of energetic fluoro species, and wherein said sensor element further comprising a fluoro-resistant coating over the at least two components.

7. The method of claim 6, wherein said fluoro-resistant coating contains material selected from the group consisting of polytetrafluoroethylene, alumina, Group II metal fluorides, perfluorinated polymers, and mixtures thereof.

8. The method of claim 1, wherein said sensor element comprises a thermistor.

9. The method of claim 1, wherein said sensor element comprises a resistance temperature detector.

10. The method of claim 9, wherein said resistance temperature detector is operated at constant current.

11. The method of claim 9, where in said resistance temperature detector is operated at constant resistance.

12. The method of claim 1, wherein the effluent gas stream is susceptible to the presence of an energetic gas species selected from the group consisting of fluorine, chlorine, iodine, bromine, oxygen, and derivatives and radicals thereof.

13. A system for determining plasma conditions in an etching plasma processing facility, comprising:
a gas sampling device for obtaining a gas sample from an effluent gas stream generated by said etching plasma processing facility at a location downstream of said etching plasma processing facility;
at least one sensor element operatively coupled with said gas sampling device for exposure to the gas sample, wherein said sensor element is capable of exhibiting temperature change in presence of energetic gas species and correspondingly generating an output signal indicative of said temperature change;
a monitoring device operatively coupled with said sensor element for monitoring the output signal generated by the sensor element that is indicative of temperature change caused by the presence of energetic gas species in said gas stream and determining the plasma conditions in said etching plasma processing facility based on said output signal.

14. The system of claim 13, wherein said gas sampling device is operatively coupled to a downstream fluid flow path through which the effluent gas stream is passed.

15. The system of claim 13, wherein said gas sampling device is part of a downstream fluid flow path through which the effluent gas stream is passed.

16. The system of claim 13, wherein said sensor element comprises at least two components that contain different metals or metal alloys and have a thermojunction therebetween.

17. The system of claim 16, wherein the at least two components of said sensor element contain metals or metal alloys selected from the group consisting of nickel, aluminum, copper, and alloys thereof.

18. The system of claim 16, wherein the effluent gas stream is susceptible to the presence of energetic fluoro species, and wherein said at least two components of the sensor element contain fluoro-resistant metals or metal alloys.

19. The system of claim 16, wherein said sensor element comprises a first component containing copper, and a second component containing constantan.

20. The system of claim 16, wherein the effluent gas stream is susceptible to the presence of energetic fluoro species, and wherein said sensor element further comprising a fluoro-resistant coating over the at least two components.

21. The system of claim 20, wherein said fluoro-resistant coating contains material selected from the group consisting of polytetrafluoroethylene, alumina, Group II metal fluorides, perfluorinated polymers, and mixtures thereof.

22. The system of claim 13, wherein said sensor element comprises a thermistor.

23. The system of claim 13, wherein said sensor element comprises a resistance temperature detector.

24. The method of claim 13, wherein said resistance temperature detector is operated at constant current.

25. The method of claim 13, where in said resistance temperature detector is operated at constant resistance.

26. The system of claim 13, wherein the effluent gas stream is susceptible to the presence of an energetic gas species selected from the group consisting of fluorine, chlorine, iodine, bromine, oxygen, and derivatives and radicals thereof.
